(19) United States
(12) Patent Application Publication
(10) Pub. No.: US 2014/0231242 A1
(43) Pub. Date: Aug. 21, 2014

(54) TOOL AND PROCESS FOR TREATING AN OBJECT BY PLASMA GENERATORS

(71) Applicant: VALEO VISION, Bobigny Cedex (FR)

(72) Inventors: Marc Brassier, Le Perreux (FR); Frederic Moret, Saint Maur Des Fosses (FR); Frederic Bretagnol, Issoire (FR)

(21) Appl. No.: 14/234,849

(22) PCT Filed: Jul. 25, 2012
(86) PCT No.: PCT/EP2012/064577

§ 371 Date: Apr. 24, 2014

(30) Foreign Application Priority Data
Jul. 29, 2011 (FR) 1156975

(51) Int. Cl. C23C 14/34

(52) U.S. Cl. CPC C23C 14/3442
USPC 204/192.11; 204/298.04; 204/298.03

(57) ABSTRACT

An apparatus for treating a surface of an object comprises a vacuum chamber in which the object is intended to be placed, and means, in communication with the vacuum chamber, for treating the surface of the object, comprising at least two plasma generator. The apparatus also comprises means for controlling each generator independently of any other generator. These controlling means comprise means for activating/deactivating the generator. The invention also relates to a process for treating a surface of an object.

### CROSS-REFERENCE TO RELATED APPLICATIONS

This application claims priority to PCT Application PCT/EP2012/064577 filed Jul. 25, 2012, and also to French Application No. 1156975 filed Jul. 29, 2011.

### BACKGROUND OF THE INVENTION

1. Field of the Invention

The present invention relates to the field of object treatment, and more particularly to the treatment of the surface of this object.

2. Description of the Related Art

An apparatus for treating an object is already known from the prior art, especially from FR-A-2 899 242, this apparatus comprising ion bombardment means intended for treating at least one surface of the object.

The ion bombardment means allow ions to be incorporated into a surface of an object, especially so as to influence the mechanical properties of this surface (hardness, tribology, etc.).

Ion bombardment means, such as those described in FR-A-2 899 242, conventionally comprise means forming an ion generator and means forming an ion applicator.

The ion applicator conventionally comprises means chosen, for example, from electrostatic lenses for shaping the ion beam, a diaphragm, a shutter, a collimator, an ion-beam analyzer and an ion-beam controller.

The ion generator conventionally comprises means chosen, for example, from an ionization chamber, an electron cyclotron resonance ion source, also called a plasma source, an ion accelerator and an ion separator.

Ion bombardment is conventionally carried out under vacuum. Thus FR-A-2 899 242 suggests housing all of the ion bombardment means (ion generator and ion applicator) and the surfaces to be treated in a vacuum chamber. Means for generating a vacuum are connected to this chamber.

These means for generating a vacuum must allow a relatively high vacuum to be obtained in the chamber, for example about 10⁻² mbar to 10⁻⁶ mbar.

However, an ion bombardment apparatus may be used to treat different objects. It is therefore necessary to dimension the apparatus to take account of the most bulky objects to be treated.

### SUMMARY OF THE INVENTION

The aim of the invention is in particular to provide an apparatus for treating the surface of an object, which apparatus can be easily adapted to the object be treated.

For this purpose the subject of the invention is an apparatus for treating a surface of an object, of the type comprising:
a vacuum chamber in which the object is intended to be placed; and
means, in communication with the vacuum chamber, for treating the surface of the object, comprising at least two plasma generators,

wherein it comprises means for controlling each generator independently of any other generator, the controlling means comprising means for activating/deactivating the generator.

The expression “at least two” is understood to mean that the apparatus comprises at least two separate plasma generators. The apparatus may comprise, for example, five, even ten or more thereof.

By virtue of this apparatus comprising a plurality of plasma generators that each comprise activating/deactivating means, it is possible to envision treating, one after the other, in the same apparatus, parts having different surfaces to be treated, while using only the plasma generators necessary to carry out the desired surface treatment.

Thus, for a given surface to be treated four generators will possibly be activated, whereas for another given surface only two generators will be activated.

It will be noted that the number of generators activated may also depend on the type of surface treatment carried out. It could, for example, be necessary to activate a greater or smaller number of generators depending on whether it is desired to carry out a plasma surface activation treatment, deposit a protective coating by plasma enhanced chemical vapor deposition (PECVD), or perform an ion bombardment treatment.

It will also be noted that the same plasma generators may be used irrespectively to carry out, in alternation, plasma treatments, i.e. surface activation treatments or PECVD treatments, and ion bombardment treatments.

Thus, for a plasma surface activation or mineralization treatment the gases most often used are chosen from air, argon (Ar), dioxygen (O₂), dinitrogen (N₂), nitrous oxide (N₂O), carbon dioxide (CO₂), water vapor (H₂O_{(g)}), ammonia (NH₃), and iodine (I₂), by themselves or as a mixture. For a PECVD deposition the gases are preferably chosen from the group containing disiloxanes such as hexamethyldisiloxane (HMDSO) or tetramethyldisiloxane (TMDSO), from the group containing aliphatic, cycloaliphatic and aromatic hydrocarbons such as methane (CH₄), ethane (C₂H₆), ethylene (C₂H₄) and cyclopentene (C₅H₈), from the group containing nitrogen derivatives such as nitroethane (C₂H₅NO₂), and from the group containing primary alcohols such as methanol (CH₄O) or ethanol (C₂H₈O), by themselves or as a mixture. This treatment allows a protective layer of very small thickness, especially comprised between 10 and 100 nm, mainly or solely made of inorganic material, to be produced on the surface of the objects. For an ion bombardment treatment the ions used for the bombardment will be ions obtained from precursor gases preferably chosen from helium (He), argon (Ar) and dinitrogen (N), by themselves or as a mixture.

The apparatus may furthermore comprise one or more of the following optional features, by themselves or in combination:
The activating/deactivating means comprise a switch.
The controlling means for example comprise means for controlling the power of the generator, means for adjusting the position of the generator or means for controlling gas flow rate.
The apparatus comprises means for identifying the object to be treated, for example an optical reader for reading a barcode or identification number of the object such as a binary code. This object identifier may be borne by the object itself or by the carrier of the object. Specifically, since the object carrier is generally specific to each object be treated the object may be identified by an identifier on its carrier.
The plasma generators are small in size, i.e. their largest dimension is smaller than 10 cm and preferably smaller than 5 cm.
The generators are arranged side-by-side and form a matrix.
The apparatus furthermore comprises vacuum sputtering or vacuum evaporation PVD depositing means. The acronym PVD (physical vapor deposition) designates a physical vapor deposition that allows a metal layer of very small thickness, especially comprised between 1 and 150 nm, and preferably between 10 and 100 nm, to be produced on the surface of the objects. This metal layer may for example be a layer of aluminum, silver, chromium, a nickel/chromium alloy, titanium, zinc and their oxides or also a stainless steel (ST 304, 306, 310, 312, 321, for example).
The same plasma generators are able to be used irrespectively to carry out, in alternation, plasma treatments, i.e. surface activation treatments or PECVD treatments, and ion bombardment treatments.
The apparatus comprises ion bombardment means and plasma treatment means, the plasma generators being common to the ion bombardment means and to the plasma treatment means.
The ion bombardment means comprise means forming an ion generator and means forming an ion applicator.

The ion applicator may comprise ion beam shaping electrostatic lenses.
The plasma generators are small in size, their largest dimension being smaller than 10 cm and preferably smaller than 5 cm.
The plasma generators are arranged side-by-side and form a matrix, for example a matrix with a single row and a plurality of columns, a plurality of rows and a single column, or even a plurality of rows and a plurality of columns.
The plasma generators comprise, to enable the ion bombardment:

two terminals connected to different potentials allowing a plasma to be created between these two terminals;

an extracting electrode allowing the species that it is desired to use for the bombardment to be selected; and

at least one accelerating electrode arranged between, on the one hand, the terminals and, on the other hand, the object the surface of which it is desired to bombard with the ions, the accelerating electrode allowing the species that it is desired to use for the bombardment to be accelerated.

The plasma generators may also comprise ion beam shaping means allowing, during the ion bombardment, the ion beam formed by the plasma generators to be focused or made to diverge, these ion beam shaping means possibly comprising an accelerating electrode the setting of the voltage of which allows the ion beam to be focused or made to diverge.

The plasma generators are arranged side-by-side and form a matrix, the ion beam shaping means allowing the respective ion beams to be made to diverge so that the ion beams of the side-by-side plasma generators overlap.

The vacuum chamber contains a movable carrier for positioning each object to be treated therein.

The carrier is mounted so as to rotate freely in the vacuum chamber about an axis of rotation.

The carrier may move in translation parallel to its axis of rotation.

The carrier is removable; thus each object to be treated may be easily positioned on the carrier before the carrier is placed in the vacuum chamber.

The carrier is a planet carrier rotatably mounted in the vacuum chamber about an axis of rotation, this planet carrier possibly bearing a plurality of planets, especially rotatably mounted on the carrier, each about an axis of rotation, these axes of rotation possibly being parallel to the axis of rotation of the planet carrier.

The vacuum chamber is capable of being placed under vacuum using pumping means allowing a vacuum comprised between 10⁻¹ mbar and 10⁻⁶ mbar to be obtained.

The apparatus is configured so that the vacuum chamber, namely the chamber intended to receive the object to be treated, is placed under a vacuum comprised between 10⁻³ mbar and 10⁻⁴ mbar while the ion bombardment is carried out.

The plasma generators each comprise an ionization chamber.

The plasma generators each comprise an ionization chamber that is connected to pumping means that are independent of the pumping means of the vacuum chamber. According to one embodiment, the apparatus, the pumping means of the plasma generators, and the pumping means of the vacuum chamber are configured to allow, simultaneously, respectively, the ionization chambers of the plasma generators to be placed under a vacuum comprised between 10-6 mbar and 10-7 mbar and the vacuum chamber to be placed under a vacuum comprised between 10-3 mbar and 10-4 mbar, while keeping these ionization chambers of the plasma generators in communication with the vacuum chamber. This pressure differential may in particular be obtained by way of differences in the power of the pumps of the pumping means. This pressure differential is employed for ion bombardment of the object to be treated.

Another subject of the invention is a process for treating a surface of an object, wherein it comprises the following steps:
attributing at least one parameter to the object;
identifying the object to be treated, the object comprising at least one surface to be treated;
placing the object to be treated in the vacuum chamber of an apparatus such as described above;
selecting each generator to be activated depending on each parameter of the identified object;
treating the object by activating each plasma generator selected in the preceding step.

The process may furthermore comprise one or more of the following optional features, by themselves or in combination:
The step of treating the object comprises a step of plasma activation of the surface, a PECVD deposition step and/or an ion bombardment step.
The plasma generators are arranged side-by-side and form a matrix, and the plasma generators comprise ion beam shaping means allowing, for the ion bombardment, the ion beams formed by the plasma generators to be focused or made to diverge, the ion beam shaping means being set so as to make the respective ion beams diverge so that the beams of the side-by-side plasma generators overlap.
The step of identifying the object to be treated is carried out by reading a barcode identifying the object.
The process comprises a step of storing parameters attributed to each object in a database.
The step of selecting each generator to be activated is carried out by a computer program.
The process comprises a plurality of successive steps of treating the surface of the object.

These and other objects and advantages of the invention will be apparent from the following description, the accompanying drawings and the appended claims.

The invention will be better understood on reading the following description given merely by way of example and with reference to the drawings in which:

### BRIEF DESCRIPTION OF THE ACCOMPANYING DRAWINGS

FIG. 1 is a schematic top view of a treatment apparatus according to a first embodiment of the invention;

FIG. 2 is a schematic cross-sectional view of a plasma generator;

FIG. 3 is a schematic top view of an apparatus according to a second embodiment of the invention; and

FIG. 4 is a view of an arrangement of plasma generators in the cross-sectional plane IV-IV in FIG. 3.

### DETAILED DESCRIPTION OF THE PREFERRED EMBODIMENTS

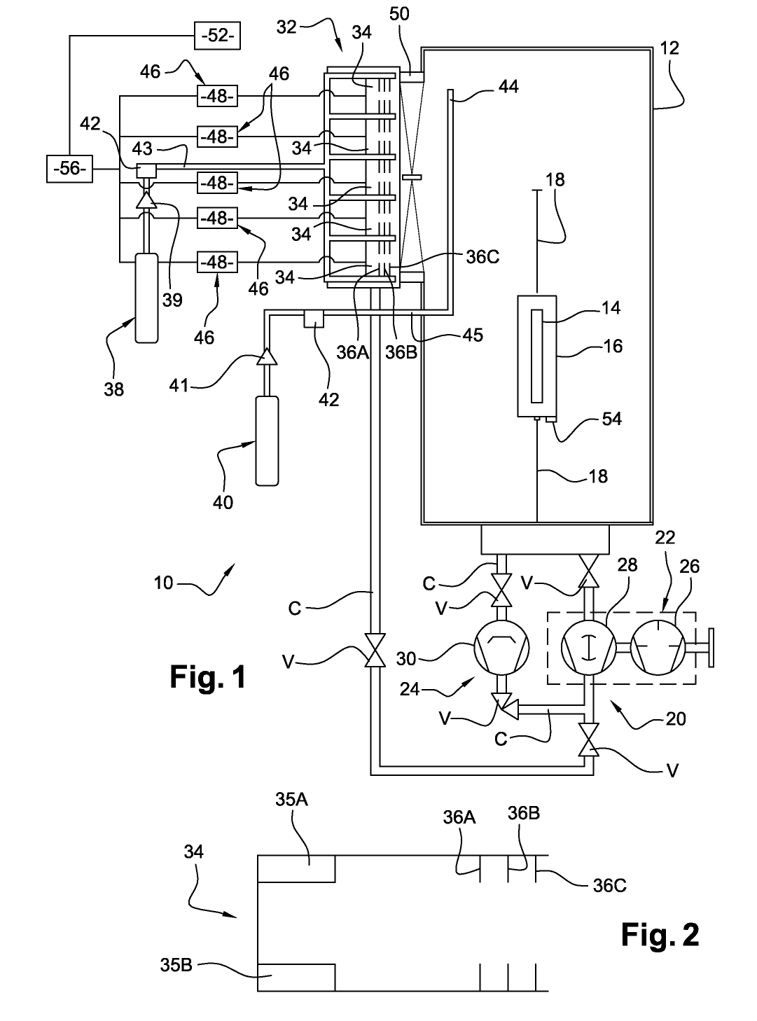

FIG. 1 shows an apparatus 10 for treating a surface of an object according to a first embodiment of the invention.

The apparatus 10 is especially intended to treat the surface of an automotive vehicle headlamp or light element, such as a mask, a trim, a plate, a casing, a reflector, a headlamp screen or a windshield wiper blade.

The apparatus 10 is intended to treat the surface of the object, especially to deposit thin layers thereon and/or to influence the mechanical and/or optical properties of the surface of the object.

The apparatus 10 comprises a vacuum chamber 12 in which at least one object 14 is intended to be placed. In this embodiment, the chamber 12 contains a removable carrier 16 mounted so as to rotate freely in the chamber 12 about an axis of rotation 18. This carrier 16 may also move in translation parallel to the axis of rotation 18. Since this carrier 16 is removable each object to be treated can easily be positioned on the carrier 16 before the carrier 16 is placed in the chamber 12.

This chamber 12 is capable of being placed under vacuum using pumping means 20 comprising a primary pumping assembly 22, allowing a vacuum of about 10⁻² mbar to be obtained, and preferably a secondary pumping assembly 24 allowing a vacuum comprised between 10⁻² mbar and 10⁻⁶ mbar to be obtained.

The primary pumping assembly 22 may, for example, comprise a mechanical rotary pump 26 mounted in series with a Roots blower 28. The mechanical rotary pump 26 allows a vacuum of about 10⁻¹ mbar to be obtained. This vacuum level allows the Roots blower 28 to be started up. The latter allows a vacuum of about 10⁻² mbar to be obtained.

Moreover, in this example the secondary pumping assembly 24 comprises a pump allowing a vacuum comprised between about 10⁻² and 10⁻⁶ mbar to be obtained, for example a diffusion pump 30.

These vacuum means 20 are connected to the apparatus 10 by ducts C and valves V that allow the various parts of the apparatus to be selectively connected, depending on the desired treatment conditions, to the pumping means 20.

The apparatus 10 comprises means 32 for treating, in the chamber 12, the surface of the object 14. These treating means 32 comprise, in the present case, five aligned plasma generators 34 arranged side-by-side and comprising electrodes 36A, 36B and 36C. These generators 34 are small in size, i.e. their largest dimension is smaller than 10 cm.

By virtue of the small size of the plasma generators 34, in comparison to conventional generators the smallest dimension of which is about 25 cm, the generators 34 can easily be arranged side-by-side without excessively increasing the bulk of the apparatus, thereby allowing the beams to be brought closer together in order to improve the uniformity of the treatment.

Advantageously, these generators 34 may be arranged sufficiently close to one another, so that it is possible to uniformly treat, using a plurality of these generators, a surface of an object 14 placed in the chamber 12.

In the embodiment in FIG. 1, the apparatus 10 allows the surface of the objects to be treated with a plasma treatment and by ion bombardment, and the generators 34 are common to the plasma treatment means and the ion bombardment means.

The apparatus 10 furthermore comprises gas-injecting means 38, 40 that especially comprise valves 39, 41, a device for controlling gas flow rate or flow controller 42, for example a calibrated mass flow controller, and ducts 43, 45 in order to inject the chosen gas at the desired location with the flow rate required for the surface treatment carried out. The injected gases may be injected by themselves or as a mixture.

In this embodiment, two different gases are injected: the first gas is injected by injecting means 38 into each plasma generator 34, and the second gas is injected into the vacuum chamber 12 by injecting means 40 that comprise a diffuser tube 44 arranged in the vacuum chamber 12 between the plasma generators 34 and the object 14 to be treated. In this example means 40 for injecting a single gas into the diffuser tube 44 have been shown. Provision may easily be made for these injecting means 40 to allow a plurality of gases of different natures, by themselves or as a mixture, to be injected into the tube 44.

In this case, the plasma treatment means employ the same plasma generators 34 as the ion bombardment means.

With reference to FIG. 2, a plasma generator 34 and its operation will now be described. To carry out an ion bombardment treatment it is necessary, after a plasma has been created between two terminals 35A and 35B, which terminals are connected to different potentials and located in the generator 34, to select the species that it is desired to use for the bombardment by means of an extracting electrode 36A, and to accelerate them by means of two accelerating electrodes 36B and 36C arranged between, on the one hand, the terminals 35A and 35B and, on the other hand, the object 14 the surface of which it is desired to bombard with the ions. The terminal 35A is, for example, connected to a reference potential and electrically isolated from the rest of the generator 34, and the terminal 35B is connected to a potential allowing the plasma to be generated between the two terminals 35A and 35B. Depending on whether these terminals 35A and 35B are supplied with a DC current or an AC current, electrodes or antennae will be spoken of, respectively.

According to one embodiment of the invention, the accelerating electrode 36C may form part of the ion beam shaping means allowing, during the ion bombardment, the ion beam formed by the plasma generator 34 to be focused or made to diverge. The accelerating electrode 36C is in this case connected to means for setting the voltage to which it is subjected. By setting this voltage it is possible to focus the ion beam or make it diverge.

To carry out a plasma treatment in this embodiment of the apparatus, the terminal 35B will be used, which, in association with the walls of the generator 34, will allow a plasma to be generated in the chamber 12, the metal walls of the chamber 12 forming the terminal connected to the reference potential. A metal element connected to the reference potential may also be placed in the chamber 12. This metal element may replace or complement the metal walls of the chamber 12.

The apparatus 10 also comprises means 46 for controlling each generator independently of any other generator. Thus, it is possible to vary the power of each plasma generator 34 independently of the other generators 34. It is also possible to control the flow rate of gas supplied to each generator 34. For the ion bombardment treatment, these controlling means 46 may also comprise means for adjusting the position of the generator and means for adjusting the angle of the emitted ion beam.

The means 46 for controlling each generator furthermore comprise means 48 for activating/deactivating the generator 34. Thus, it is possible to choose whether a generator 34 is activated or not independently of any other generator 34. These activating/deactivating means 48 may comprise a switch.

The apparatus 10 also comprises isolating means 50 for isolating the plasma generators 34 from the vacuum chamber 12. These isolating means 50 for example comprise a gate that may be closed or opened depending on whether or not it is desired to isolate the generators 34 from the vacuum chamber 12.

Thus, during operations for loading/unloading the vacuum chamber 12 the gate 50 may be closed so that the generators 34 may remain under vacuum whereas the chamber 12 is returned to atmosphere.

For a new surface treatment operation, all that is required is to recreate appropriate vacuum conditions in the chamber 12 before once more bringing this chamber 12 into communication with the generators 34.

Thus it is possible, during operations for loading/unloading the vacuum chamber 12, to maintain, in the immediate environment of the plasma generators 34, a vacuum level quite close to that desired in the chamber 12 for treating an object. This allows the time and power required to return the chamber 12 and the generators 34 to appropriate vacuum conditions after each operation for loading/unloading this chamber to be optimized.

In this embodiment, the apparatus 10 also comprises means 52 for identifying the object 14 to be treated, such as, for example, an optical reader able to read a barcode 54 identifying the object 14. The barcode 54 is here borne by the carrier 16, which is specific to the object 14 to be treated.

The controlling means 46 and the identifying means 52 are controlled by means of a PLC (programmable logic controller) computer program 56 or even by means of an industrial computer.

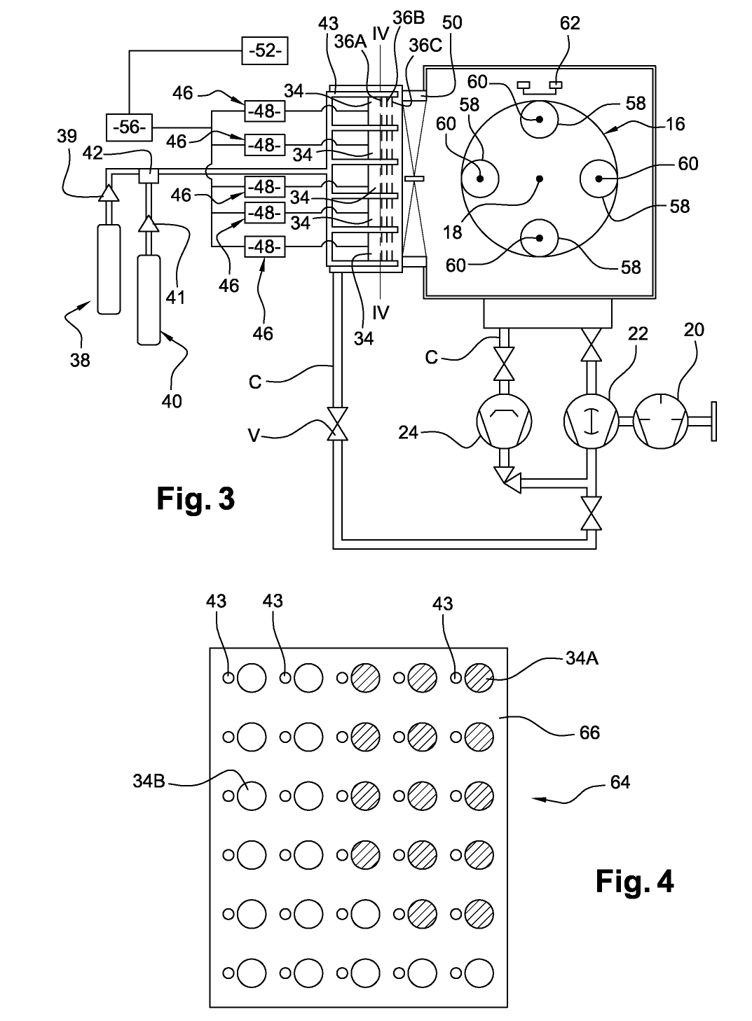

FIG. 3 shows a second embodiment of the apparatus, in which elements common to both embodiments are identified by the same reference numbers.

In this embodiment, the carrier 16 is a planet carrier rotatably mounted in the chamber 12 about an axis of rotation 18. This planet carrier 16 bears a plurality of planets 58 rotatably mounted on the carrier 16, each about an axis of rotation 60. These axes of rotation 60 are, in the present case, parallel to the axis of rotation 18 of the planet carrier 16. These planets 58, in this example four in number, are each intended to bear at least one object 14 to be treated. This planet carrier 16 may also move in translation parallel to the axis of rotation 18.

However, it will be noted that, in the second embodiment, the injecting means 38, 40 are arranged differently than in the first embodiment. Specifically, in this second embodiment, the two gases are injected into the plasma generators 34. In addition, in this second embodiment, the two gases may be mixed before they arrive in the generator.

In this embodiment, since the gases are delivered directly to the plasma generators, during a plasma treatment the terminals 35A and 35B of the generator 34 will be used to create the plasma, and not the terminal 35B and the metal walls of the chamber 12 as in the preceding embodiment. Advantageously, the apparatus 10 shown in FIG. 3 also comprises PVD depositing means 62 housed in the vacuum chamber 12. During a PVD treatment it is desirable to close the gate 50 in order to isolate the plasma generators 34 from the vacuum chamber 12 and thus protect them from any metal deposition that could, in the long term, damage the generators. In addition, for this type of deposition the vacuum level required is different and closing the gate 50 allows the plasma generators 34 to be kept under appropriate vacuum conditions.

FIG. 4 shows an array 64 of generators 34 for the apparatus 10 shown in FIG. 3. This array 64 comprises thirty generators 34 distributed in six rows and five columns on a carrier 66 for a given treatment of the surface of one or more identified objects 14 placed in the vacuum chamber 12. The carrier 66 has a substantially rectangular shape and is substantially flat. It will be understood that the shape of the carrier 66 is not limited to a rectangle. It is possible to imagine, for example, in the case of a chamber 12 a wall of which is cylindrical, this carrier 66 closely following the shape of the wall of the chamber 12. This carrier 66 could also have a curved shape in order to allow certain surfaces of the objects 14 to be treated to be reached, independently of the shape of the chamber 12.

The hashed generators 34A represent the generators that are activated during the surface treatment whereas the other generators 34B represent the generators that will be deactivated for this treatment. It will be noted that, in this example, fourteen generators are activated.

For another treatment of the same object a different number of generators 34 or even the same number of generators 34 could be activated, these activated generators 34A however having a different distribution.

Thus, the activated generators 34A are selected for a given object 14 and for a given treatment.

It will be noted that an array 64 of generators 34 arranged in rows and columns has been shown. However, an array of staggered generators could also have been shown.

It will be noted that the surface to be treated of the object 14 may be different depending on the type of treatment that is applied to the object 14. Thus, it may be desired to carry out a PVD deposition on one surface of the object 14 and carry out the ion bombardment on another surface of the object 14. These surfaces may however completely or partially overlap.

It may also be envisioned to use, to create the plasma, known means that transfer the energy generated by a quartz crystal excited at microwave frequencies.

Lastly, it will be noted that the invention is not limited to the embodiments described above. Thus, although plasma generators common to the ion bombardment means and plasma treatment means were described, it may also be envisioned to provide a plurality of plasma generators at least two of which are dedicated to a specific treatment type. The carriers 16 of the first and second embodiments are interchangeable and are not limited to those described. The first embodiment may also comprise PVD deposition means 62 housed in the vacuum chamber 12, and generators arranged in a matrix.

### Example 1

### Process for Treating One or More Objects 14

An example of a process for treating a surface of an object in an apparatus such as described above will now be described.

Considering an object 14 a surface of which it is desired to treat, different parameters of the object 14, such as the surface or the surfaces to be treated, the type of surface treatment to be carried out, the sequence of treatments, the geometry of the object, etc. are determined. These parameters especially make it possible to select, for a given surface treatment, each generator to be activated, the power to supply to each generator, whether or not to supply the ion-extracting electrode 36A and the ion-accelerating electrodes 36B and 36C, the nature of the gas to be used, and the gas flow rate required.

These parameters are stored in a database, these parameters being linked, in the database, to an identifier of the object 14. This identifier may, for example, be a barcode 54 associated with the object 14. This database is hosted on the computer 56 on which the PLC program is executed. It may also be envisioned for the database to be hosted on another computer.

When the object 14 is ready to be treated in the apparatus 10, the object 14 is placed on its specific carrier 16, and the object is identified by virtue of the identifying means 52 that allow the barcode 54 borne by the carrier 16 of the object 14 to be read. This identification allows parameters associated with the object 14 and the sequence of treatments that must be applied to it to be retrieved from the database. The treatment parameters are transmitted to the PLC program which controls the pumping means 20, the means 46 for controlling each generator 34 and the required gas flows.

Next, the assembly of the carrier 16 and the object 14 are placed in the vacuum chamber 12 and vacuum conditions appropriate to the various surface treatments that it is desired to carry out are generated i.e. a vacuum of about 10⁻³ mbar.

Once appropriate vacuum conditions have been generated, the gate 50 is opened in order to bring the generators 34, kept beforehand at a vacuum level of about 10⁻⁶ mbar, into communication with the chamber 12.

An ion bombardment treatment using a beam of singly charged helium ions (He+) is for example carried out. By virtue of the identification of the object 14, the PLC program will in particular selectively activate the generators 34 required for each treatment.

For example, the bombardment is carried out, on the one hand, by exciting the small generators 34A at a frequency of 2.45 GHz in order to strike the plasma and, on the other hand, by supplying them with helium. The plasma thus created, the He ions are extracted by means of the electrode 36A brought to a potential of 30 kV, and then accelerated by the electrode 36B brought to a potential of 25 kV and a current of 1 mA and the electrode 36C brought to a potential of zero (grounded) and a current of 1 mA.

The PLC program or the industrial computer may furthermore control the speed of rotation of the carrier 16 in order to control the treatment time of each surface of the object 14. In the present case, the speed of rotation is defined to correspond to a surface treatment time of 3 seconds, corresponding to a received He ion dose of 6×10¹⁵ ions/cm².

At the end of the ion bombardment treatment the gate 50 is closed and pumping is carried out to reach 10⁻⁵ mbar, under which conditions a PVD deposition of an aluminum layer comprised between 50 and 70 nm in thickness is carried out.

Once the aluminum layer has been deposited, an amount of HMDSO monomer corresponding to a flow rate of 100 sccm (standard cubic centimeters per minute) is injected through the flow controller 42.

When the pressure has stabilized at 5×10⁻² mbar, the gate 50 is opened in order to bring all of the generators into communication with the chamber.

The generators 34 required for this treatment are selectively supplied at a frequency of 2.45 GHz in order to strike the HMDSO plasma. In the plasma the monomers polymerize and deposit on the object 14, forming a transparent protective layer on the aluminum layer deposited beforehand by PVD.

In this example, the gas injection and supply of the generators 34 are stopped after 60 seconds allowing a deposit having a thickness comprised between 25 and 40 nm to be obtained.

Next, the gate 50 is closed and the chamber 12 is returned to atmospheric pressure in order to extract each treated object 14 therefrom.

The apparatus 10 is then available to treat one or more new objects.

It is also possible to modify the PVD and PECVD deposits by carrying out an ion bombardment at the same time as the PVD or PECVD deposition.

It is also possible to envision carrying out this plurality of treatments simultaneously by distributing the generators 34 of the array 64 between the various surface treatments that it is desired to carry out.

### Example 2

### Gas Mixtures

For the ion bombardment, it is possible to envision using gas mixtures chosen from He/Ar (for example with a gas flow ratio of 80/20 or 50/50), He/N₂ (for example with a gas flow ratio of 80/20 or 20/80) and He/Ar/N₂ (for example with a gas flow ratio of 60/20/20) mixtures.

For the plasma treatment, the following mixtures may be used: air/Ar (for example with a gas flow ratio of 60/40), Ar/N₂ (for example with a gas flow ratio of 50/50), Ar/N₂O (for example with a gas flow ratio of 50/50 or 80/20), HMDSO/TMDSO (for example with a gas flow ratio of 80/20), HMDSO/N₂O/Ar (for example with a gas flow ratio of 70/10/20), CH₄/N₂O (for example with a gas flow ratio of 80/20), or HMDSO/N₂O/O₂ (for example with a gas flow ratio of 80/10/10).

Furthermore, in the case of gas mixtures, the gases may be mixed upstream of the generators 34 via selective supply of the generators 34. For example, for an He/Ar mixture (for example with a gas flow ratio of 80/20) the two gases may either be premixed before arriving at the generator 34, or 80% of the activated generators may supply singly charged helium ions He and 20% of the activated generators singly charged helium ions Ar⁺. It may also be envisioned to supply the generators 34 with helium, then to supply them with argon.

### Example 3

### Successive Treatment Sequences with Different Gases

It is also possible to carry out a sequential treatment, each sequence using a different gas under specific conditions.

For example, with the following sequences:

| | Precursor | Extraction | | Treatment |
|---|---|---|---|---|
| | gas | voltage | Dose | time |
| Sequence 1 | He | 30 kV | 6 × 10¹⁵ ions/cm² | 2 s |
| Sequence 2 | N₂ | 20 kV | 1 × 10¹⁶ ions/cm² | 3 s |
| Sequence 3 | I₂ | 5 kV | 1 × 10¹⁴ ions/cm² | 5 s |

It is also possible, instead of carrying out treatment sequentially, to carry out these treatments (for example the above three) simultaneously but using a different spatial distribution in a matrix of plasma generators.

While the system, apparatus, process and method herein described constitute preferred embodiments of this invention, it is to be understood that the invention is not limited to this precise system, apparatus, process and method, and that changes may be made therein without departing from the scope of the invention which is defined in the appended claims.

What is claimed is:

1. An apparatus for treating a surface of an object, of the type comprising:
a vacuum chamber in which the object is intended to be placed; and
means, in communication with the vacuum chamber, for treating the surface of the object, comprising at least two plasma generators,
wherein it comprises means for controlling each generator independently of any other generator, the controlling means comprising means for activating/deactivating the generator.

2. The apparatus as claimed in claim 1, in which the activating/deactivating means comprise a switch.

3. The apparatus as claimed in claim 1, in which the controlling means comprises means for controlling the power of the generator, means for adjusting the position of the generator or means for controlling gas flow rate.

4. The apparatus as claimed in claim 1, comprising means for identifying the object to be treated, for example an optical reader for reading a barcode or identification number of the object.

5. The apparatus as claimed in claim 1, in which the same plasma generators are able to be used irrespectively to carry out, in alternation, plasma treatments and ion bombardment treatments.

6. The apparatus as claimed in claim 1, in which the plasma generators are small in size, their largest dimension being smaller than 10 cm.

7. The apparatus as claimed in claim 1, in which the plasma generators are arranged side-by-side and form a matrix.

8. The apparatus as claimed in claim 1, in which said vacuum chamber contains a movable carrier for positioning each object to be treated therein.

9. The apparatus as claimed in claim 8, in which the carrier is mounted so as to rotate freely in said vacuum chamber about an axis of rotation.

10. A process for treating a surface of an object, wherein the method comprises the following steps:
attributing at least one parameter to the object;
identifying the object to be treated, the object comprising at least one surface to be treated;
placing the object to be treated in the vacuum chamber of an apparatus as claimed in claim 1;
selecting each generator to be activated depending on each parameter of the identified object;
treating the object by activating each plasma generator selected in the preceding step.

11. The process as claimed in claim 10, in which the step of treating the object comprises a step of plasma activation of the surface, a PECVD deposition step and/or an ion bombardment step.

12. The process as claimed in claim 10, in which the step of identifying the object to be treated is carried out by reading a barcode identifying the object.

13. The process as claimed in claim 10, comprising a step of storing parameters attributed to each object in a database.

14. The process as claimed in claim 10, in which the step of selecting each generator to be activated is carried out by a computer program.

15. The process as claimed in claim 10, comprising a plurality of successive steps of treating the surface of the object.

16. The process as claimed in claim 10, in which the plasma generators are arranged side-by-side and form a matrix, the generators comprising ion beam shaping means allowing, for the ion bombardment, the ion beam formed by the plasma generators to be focused or made to diverge, the ion beam shaping means being set so as to make the respective ion beams diverge so that the beams of the side-by-side plasma generators overlap.

17. The apparatus as claimed in claim 1, in which the plasma generators are small in size, their largest dimension being smaller than 5 cm.

18. An apparatus for treating a surface of an object, of the type comprising:
a vacuum chamber in which the object is intended to be placed; and
at least two plasma generators in communication with the vacuum chamber, for treating the surface of the object,
a controller for controlling each generator independently of any other generator.

19. The apparatus as claimed in claim 18, in which the controller controls: power of the generator, adjusting a position of each of the at least two plasma generators or controlling gas flow rate.

20. The apparatus as claimed in claim 18, in which the same at least two plasma generators are able to be used irrespectively to carry out, in alternation, plasma treatments and ion bombardment treatments.
